(19) United States
(12) Patent Application Publication
(10) Pub. No.: US 2026/0082856 A1
(43) Pub. Date: Mar. 19, 2026

(54) SUBSTRATE TREATMENT LINE

(71) Applicant: KCTech CO., LTD., Gyeonggi-do (KR)

(72) Inventors: Hee Sung CHAE, Gyeonggi-do (KR); Seung Eun LEE, Seoul (KR); Geun Sik YUN, Gyeonggi-do (KR)

(73) Assignee: KCTech CO., LTD., Gyeonggi-do (KR)

(21) Appl. No.: 19/398,040

(22) Filed: Nov. 24, 2025

Related U.S. Application Data
(63) Continuation of application No. 17/671,053, filed on Feb. 14, 2022.

(30) Foreign Application Priority Data
Aug. 24, 2021 (KR) 10-2021-0111935

(51) Int. Cl. H01L 21/677; B08B 13/00; B25J 15/00; H01L 21/67; H01L 21/687

(52) U.S. Cl. CPC H10P 72/3312; B08B 13/00; B25J 15/0052; H10P 72/0458; H10P 72/0468; H10P 72/3302; H10P 72/7602

(57) ABSTRACT

A substrate treatment line is disclosed. The substrate treatment line may include a chamber portion including a plurality of treatment chambers stacked in a vertical direction, and a vertical return robot, including a plurality of gripping portions, to transfer a plurality of substrates in a vertical direction simultaneously and load or unload the substrates to the treatment chambers.

### CROSS-REFERENCE TO RELATED APPLICATION

This application is a continuation application of and claims the priority benefit of a prior application Ser. No. 17/671,053, filed on Feb. 14, 2022, now pending, which claims the priority benefit of Korea application serial No. 10-2021-0111935, filed on Aug. 24, 2021. The entirety of each of the above-mentioned patent applications is hereby incorporated by reference herein and made a part of this specification.

### BACKGROUND

### Technical Field

One or more example embodiments relate to a substrate treatment line.

### Description of Related Art

In general, semiconductors are manufactured by iteratively performing a series of processes such as lithography, deposition, and etching. Contaminants such as various particles, metal impurities, or organic materials remain on a surface of a substrate of a semiconductor due to the iterative processes. Due to such contaminants on the substrate, the semiconductor may be less reliable. To remove the contaminants, a process of cleaning and drying a substrate, that is, a substrate treatment process in a semiconductor manufacturing process is required.

Meanwhile, the substrate treatment process requires a process of loading, unloading, or transferring a substrate from or to a plurality of treatment chambers, and such processes consume a tremendous amount of time in a semiconductor manufacturing process. Accordingly, there is a demand for a substrate treatment line having a parallel structure to clean or dry a plurality of substrates simultaneously.

The above description is information the inventor(s) acquired during the course of conceiving the present disclosure, or already possessed at the time, and is not necessarily art publicly known before the present application was filed.

### SUMMARY

Example embodiments provide a substrate treatment line to treat a plurality of substrates simultaneously.

Example embodiments provide a substrate treatment line to provide an efficient path for a substrate.

Example embodiments provide a substrate treatment line to allow a rapid treatment for a substrate.

According to an aspect, there is provided a substrate treatment line including a chamber portion including a plurality of treatment chambers stacked in a vertical direction, and a vertical return robot, including a plurality of gripping portions, to transfer a plurality of substrates in a vertical direction simultaneously and load or unload the substrates to the treatment chambers.

A plurality of the chamber portions may be provided and are each disposed at an interval in a horizontal direction, and the substrate treatment line may further include a horizontal return robot to transfer the substrates between the chamber portions in a horizontal direction.

The chamber portion may include a first chamber portion and a second chamber portion.

The vertical return robot may include a first vertical return robot to load, unload, or vertically transfer the substrates from or to the first chamber portion and a second vertical return robot to load, unload, or vertically transfer the substrates from or to the second chamber portion.

The treatment chambers of the first chamber portion may include a first treatment chamber, a second treatment chamber, and a third treatment chamber, and the treatment chambers of the second chamber portion may include a fourth treatment chamber and a fifth treatment chamber.

The first treatment chamber, the second treatment chamber, and the third treatment chamber may be sequentially stacked on each other from bottom to top, and the fourth treatment chamber and the fifth treatment chamber may be sequentially stacked on each other from top to bottom.

The first to third treatment chambers may be each provided as a contact cleaning chamber, and the fourth and fifth treatment chambers may be each provided as a non-contact cleaning chamber or a drying chamber.

The first vertical return robot may include a first gripping portion, a second gripping portion and a third gripping portion to grip a substrate.

The first vertical return robot may transition between a first state having a first height and a second state having a second height that is higher than the first height.

In the first state, the first to third gripping portions may be placed at heights corresponding to the first to third treatment chambers.

In the first state, the first vertical return robot may grip and unload substrates treated in the first to the third treatment chambers.

The first vertical return robot may transition to the second state in which the first and the second gripping portions load substrates to the second and third treatment chambers and the third gripping portion loads a substrate to a first point, and may transition to the first state.

The second vertical return robot may include a fourth gripping portion and a fifth gripping portion to grip a substrate.

The second vertical return robot may transition between a third state having a third height and a fourth state having a fourth height that is lower than the third height.

In the fourth state, the fourth and fifth gripping portions may be placed at heights corresponding to the fourth to fifth treatment chambers.

In the third state, the second vertical return robot may grip and unload a substrate placed on a second point and a substrate treated in the fourth treatment chamber.

The second vertical return robot may transition to the fourth state in which the fourth and the fifth gripping portions load substrates to the fourth and fifth treatment chambers and may transition to the third state.

The horizontal return robot may include a sixth gripping portion to grip a substrate placed on the first point and transfer the substrate to the second point.

Additional aspects of example embodiments will be set forth in part in the description which follows and, in part, will be apparent from the description, or may be learned by practice of the disclosure.

According to example embodiments, a substrate treatment line may treat a plurality of substrates simultaneously.

According to example embodiments, a substrate treatment line may provide an efficient path for a substrate.

According to example embodiments, a substrate treatment line may allow a rapid treatment for a substrate.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a schematic perspective view of a substrate treatment line according to an example embodiment;

FIGS. 2A to 2G are schematic front views to illustrate a substrate treatment process;

FIGS. 3A to 3G are schematic front views to illustrate a substrate treatment process; and

FIGS. 4A to 4C are schematic front views to illustrate a substrate treatment process.

### DESCRIPTION OF THE EMBODIMENTS

Hereinafter, example embodiments will be described in detail with reference to the accompanying drawings. However, various alterations and modifications may be made to the example embodiments. Here, the example embodiments are not construed as limited to the disclosure. Here, the example embodiments are not construed as limited to the disclosure and should be understood to include all changes, equivalents, and replacements within the idea and the technical scope of the disclosure.

The terminology used herein is for the purpose of describing particular example embodiments only and is not to be limiting of the example embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the example embodiments with reference to the accompanying drawings, like reference numerals refer to like constituent elements and a repeated description related thereto will be omitted. In the description of example embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The same name may be used to describe an element included in the example embodiments described above and an element having a common function. Unless otherwise mentioned, the descriptions on the example embodiments may be applicable to the following example embodiments and thus, duplicated descriptions will be omitted for conciseness.

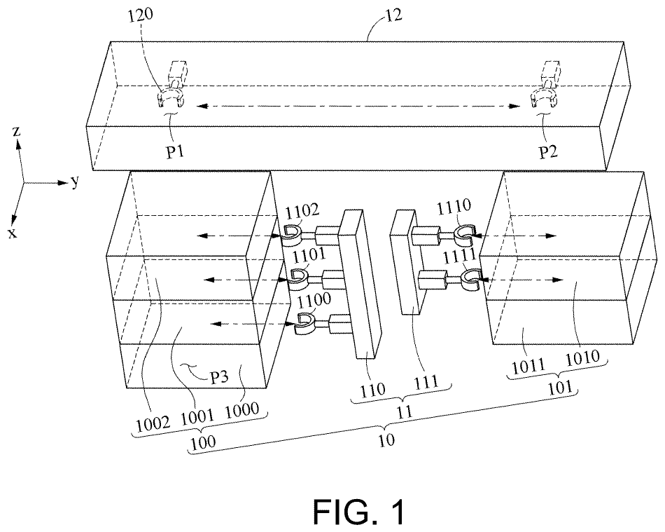

FIG. 1 is a schematic perspective view of a substrate treatment line 1 according to an example embodiment.

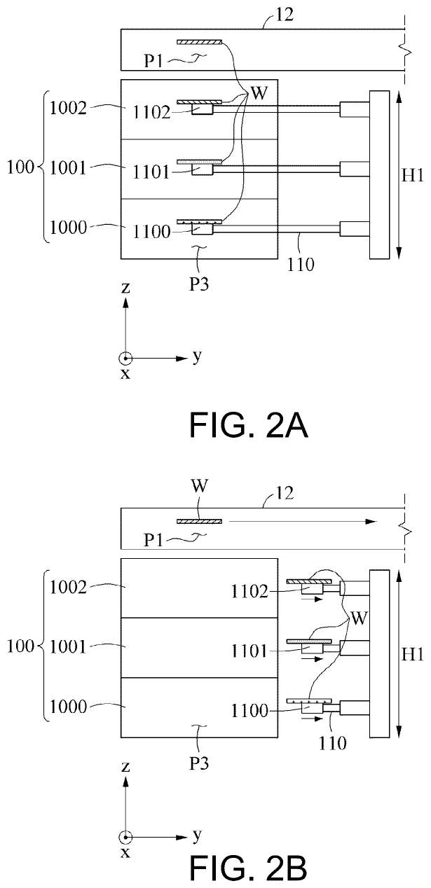

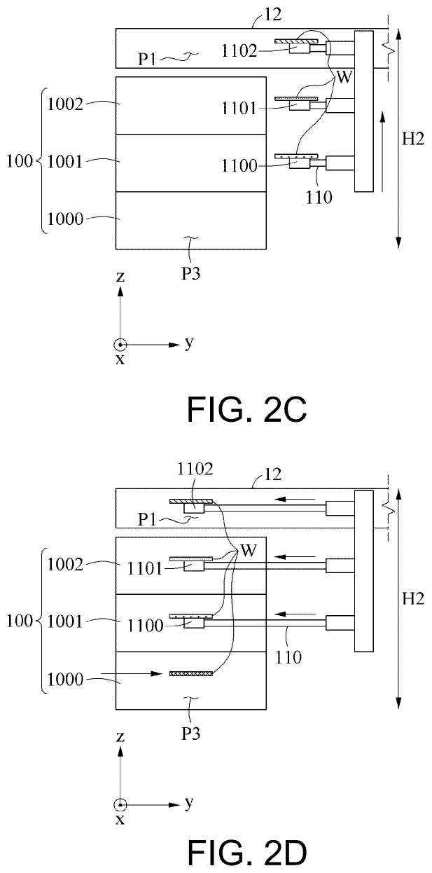

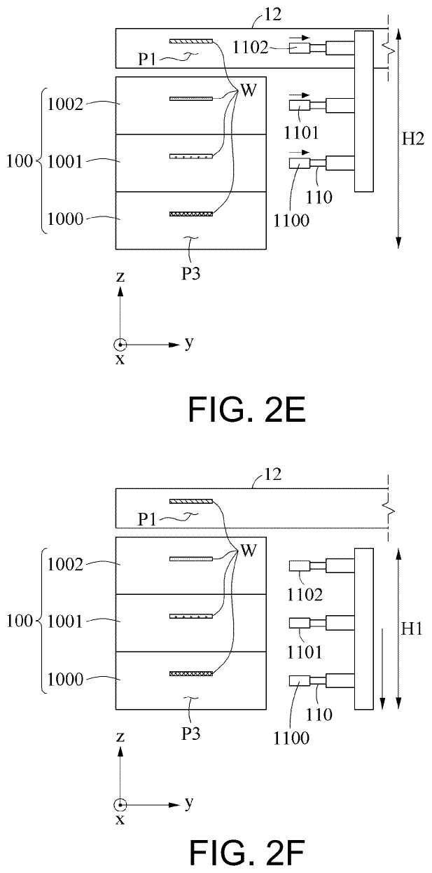

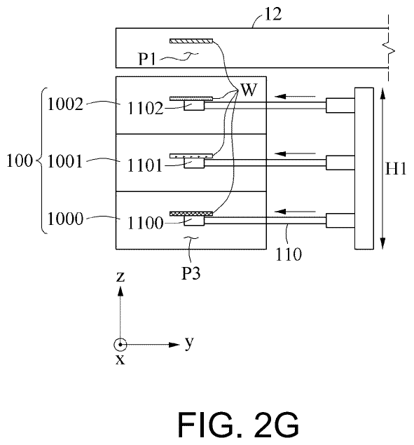

Referring to FIG. 1, the substrate treatment line 1 may be used in a substrate treatment process to treat a polished substrate (for example, a substrate W of FIGS. 2A to 4G). The substrate treatment line 1 may include a chamber portion 10, a vertical return robot 11, and a horizontal return robot 12.

The substrate W may be a silicon wafer for a semiconductor substrate. However, the type of the substrate is not limited to the foregoing example. The substrate may include, for example, glass for a liquid crystal display (LCD), a plasma display panel (PDP), and a flat panel display (FPD). In addition, the substrate W is not limited to a particular shape and size and may be substantially any shape and size. For example, the substrate W may be a circle and a squared plate.

The chamber portion 10 may provide a space in which a treatment process on the substrate W is performed. The substrate treatment process may include a substrate cleaning process and a substrate drying process. A plurality of the chamber portions 10 may be provided and are each disposed at an interval in a vertical direction (for example, a direction of an y axis). For example, the chamber portion 10 may include a first chamber portion 100 and a second chamber portion 101. However, this is an example, and a number of the chamber portions 10 is not limited thereto. The chamber portion 10 may include at least one treatment chamber.

The treatment chamber may perform a treatment process on a polished substrate W. A plurality of treatment chambers may be provided. For example, the first chamber portion 100 may include a first treatment chamber 1000, a second treatment chamber 1001, and a third treatment chamber 1002. In addition, the second chamber portion 101 may include a fourth treatment chamber 1010 and a fifth treatment chamber 1011. However, this is an example, and a number of treatment chambers is not limited thereto. At least a portion of the treatment chambers may be stacked in a vertical direction. For example, the first treatment chamber 1000, the second treatment chamber 1001, and the third treatment chamber 1002 may be sequentially stacked from bottom to top (for example, in a +z axis direction) based on a ground. In addition, the fourth treatment chamber 1010 and the fifth treatment chamber 1011 may be sequentially stacked from top to bottom (for example, in a −z axis direction) based on the ground. However, this is an example, and a disposition of the treatment chambers is not limited thereto. The treatment chamber may clean or dry the substrate W. For example, the first to third treatment chambers 1000, 1001, and 1002 may each be provided as a contact cleaning chamber, and the fourth and the fifth cleaning chambers 1010 and 1011 may each be provided as a non-contact cleaning chamber or a drying chamber. In addition, inside the treatment chamber, a nozzle to provide a fluid for performing a treatment process may be provided. However, this is an example, and a method of treating the substrate W by the treatment chamber is not limited thereto.

A polished substrate W may be loaded to a third point P3 of the first treatment chamber 1000. For example, a separate robot (not shown) may load the polished substrate W to the third point P3 of the first treatment chamber 1000. The third point P3 may function as a stage before the first vertical return robot 110, which is described below, unloads the substrate W. The substrate W, on which treatment is performed in the substrate treatment line 1 may be unloaded through the fifth treatment chamber 1011. For example, a separate robot (not shown) may unload the substrate W on which treatment is performed through the fifth treatment chamber 1011. However, this is an example, and a method of loading or unloading the substrate W before or after a treatment is not limited thereto. In addition, a place where the polished substrate W is loaded and the treated substrate W is unloaded is not limited to the first treatment chamber 1000 and the fifth treatment chamber 1011.

A vertical return robot 11 may transfer the substrate W in a vertical direction and may load or unload the substrate W to the treatment chamber. For example, the vertical return robot 11 may transfer a plurality of substrates W simultaneously in a vertical direction and may load or unload the substrates W to the treatment chambers respectively. However, this is an example, and an operation of the vertical return robot 11 is not limited thereto. A plurality of the vertical return robots 11 may be provided. For example, the vertical return robot 11 may include a first vertical return robot 110 and a second vertical return robot 111. For example, the first vertical return robot 110 may load, unload, or vertically transfer the substrate W from or to the first chamber portion 100 and the second vertical return robot 111 may load, unload, or vertically transfer the substrate W from or to the second chamber portion 101. However, this is an example, and a number and disposition of the vertical return robots 11 are not limited thereto. The vertical return robot 11 may include a gripping portion.

The gripping portion may stably transfer the substrate W by gripping the substrate W. A plurality of the gripping portions may be provided. For example, a number of the gripping portions may correspond to a number of the treatment chambers. For example, the first vertical return robot 110 may include a first gripping portion 1100, a second gripping portion 1101, and a third gripping portion 1102 and the second vertical return robot 111 may include a fourth gripping portion 1110 and a fifth gripping portion 1111. However, this is an example, and the number and disposition of the gripping portions are not limited thereto.

A horizontal return robot 12 may transfer the substrate W between the chamber portions 10 in a horizontal direction (for example, in a y axis direction) based on the ground. The horizontal return robot 12 may include a sixth gripping portion 120. The sixth gripping portion 120 may stably transfer the substrate W by gripping the substrate W. The sixth gripping portion 120 may move between the first point P1 and a second point P2 of the horizontal return robot 12.

FIGS. 2A to 2G are schematic front views to illustrate a treatment process of the substrate W.

Referring to FIGS. 2A to 2G, the substrate treatment line 1 may treat a plurality of substrates W simultaneously.

The first vertical return robot 110 may iteratively reciprocate between a first state (for example, FIGS. 2A, 2B, 2F and 2G) having a first height H1 and a second state (for example, FIG. 2C or 2E) having a second height H2 that is higher than the first height H1.

In FIGS. 2A and 2B, in the first state, the first to third gripping portions 1100, 1101, and 1102 may be placed at a height corresponding to the first to third treatment chambers 1000, 1001, and 1002. The first vertical return robot 110 may grip and unload the substrates W on which treatments are performed in the first to third treatment chambers 1000, 1001, and 1002. For example, the first to third gripping portions 1100, 1101, and 1102 may grip and unload the substrates W from the first to third treatment chambers 1000, 1001, and 1002. The first vertical return robot 110 transferring the substrates W may transition from the first state to the second state after unloading the substrates W.

Referring to FIGS. 2A and 2B, the horizontal return robot 12 may transfer the substrates W placed on the first point P1 to the second point P2 (for example, the second point P2 of FIG. 1).

Referring to FIGS. 2C to 2E, in the second state, the first and second gripping portions 1100 and 1101 may be placed at heights corresponding to the first and second treatment chambers 1000 and 1001 and the third gripping portion 1102 may be placed at a height corresponding to the first point P1. The first vertical return robot 110 may load the substrates W to the second and third treatment chambers 1001 and 1002, and to the first point P1. For example, the first and second gripping portions 1100 and 1101 may load the substrates W to the second and third treatment chambers 1001 and 1002 and the third gripping portion 1102 may load the substrates W to the first point P1. The first vertical return robot 110 may transition from the second state to the first state.

Referring to FIGS. 2F and 2G, in the first state, the first vertical return robot 110 may grip and unload the substrate W on which treatments are performed in the first to third treatment chambers 1000, 1001, and 1002. The example is substantially same as the examples of FIGS. 2A and 2B, so the details thereof have been omitted.

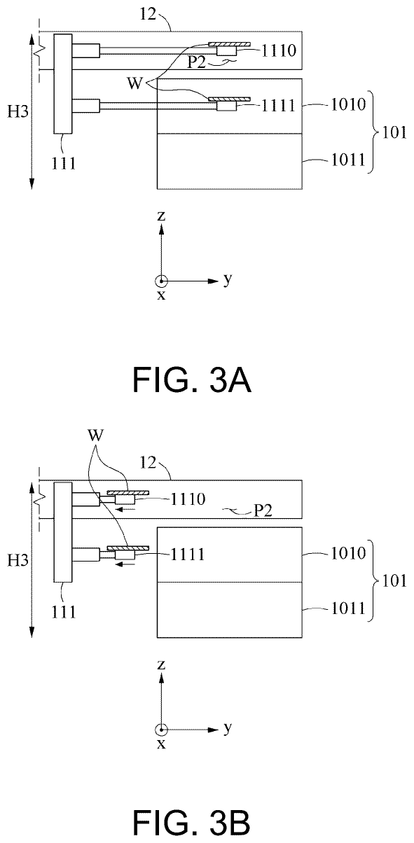

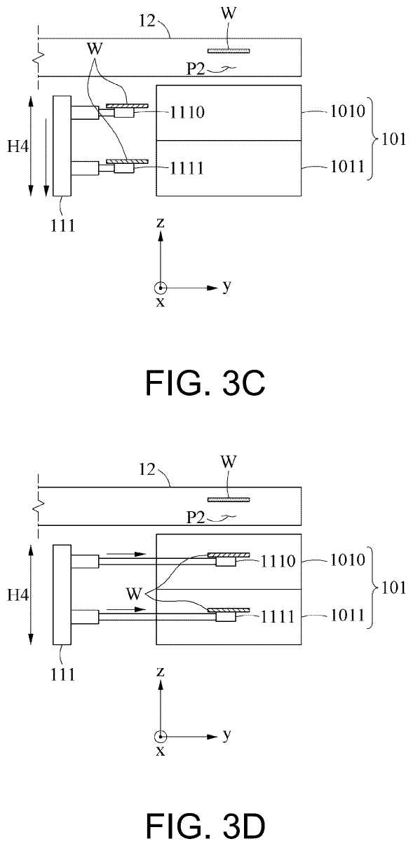

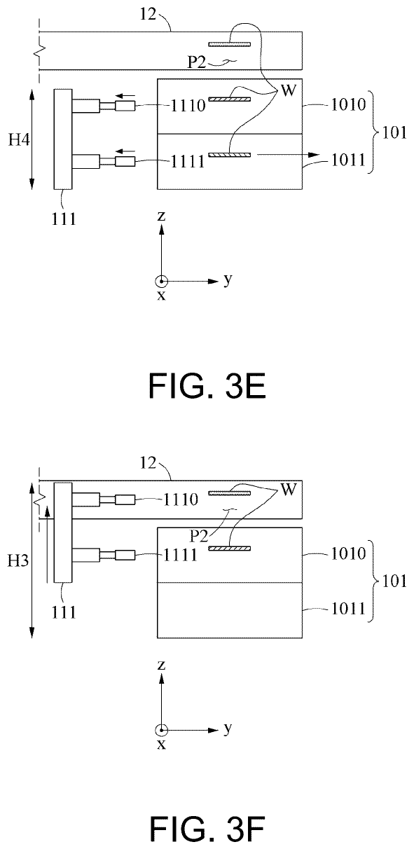

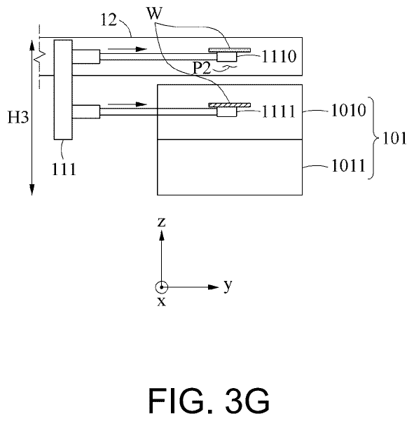

Referring to FIGS. 3A to 3G, the substrate treatment line 1 may treat a plurality of substrates W simultaneously.

The second vertical return robot 111 may iteratively reciprocate between a third state (for example, FIGS. 3A, 3B, and 3F) having a third height H3 and a fourth state (for example, FIGS. 3C to 3E) having a fourth height H4 that is lower than the third height H3.

Referring to FIGS. 3A and 3B, in the third state, the fourth gripping portion 1110 may be placed at a height corresponding to the second point P2 and the fifth gripping portion 1111 may be placed at a height corresponding to the fourth treatment chamber 1010. The second vertical return robot 111 may grip and unload the substrate W placed on the second point P2 and the substrate W on which treatment is performed in the fourth treatment chamber 1010. For example, the fourth gripping portion 1110 may grip and unload the substrate W placed on the second point P2 and the fifth gripping portion 1111 may grip and unload the substrate W on which treatment is performed in the fourth treatment chamber 1010. The second vertical return robot 111 transferring the substrate W may transition from the third state to the fourth state after unloading the substrate W.

Referring to FIGS. 3C to 3E, in the fourth state, the fourth and fifth gripping portions 1110 and 1111 may be placed at heights corresponding to the fourth and fifth treatment chambers 1010 and 1011. The second vertical return robot 111 may load a substrate W to the fourth and fifth treatment chambers 1010 and 1011. For example, the fourth and fifth gripping portions 1110 and 1111 may load the substrates W to the fourth and fifth treatment chambers 1010 and 1011. The second vertical return robot 111 may transition from the fourth state to the third state.

Referring to FIGS. 3C to 3E, the horizontal return robot 12 may transfer the substrate W placed on the first point (for example, the first point P1 of FIG. 1) to the second point P2.

Referring to FIGS. 3F and 3G, in the third state, the second vertical return robot 111 may grip and unload the substrate W placed on the second point and the substrate W treated in the fourth treatment chamber 1010. The example is substantially same as the examples of FIGS. 3A and 3B, so the details thereof have been omitted.

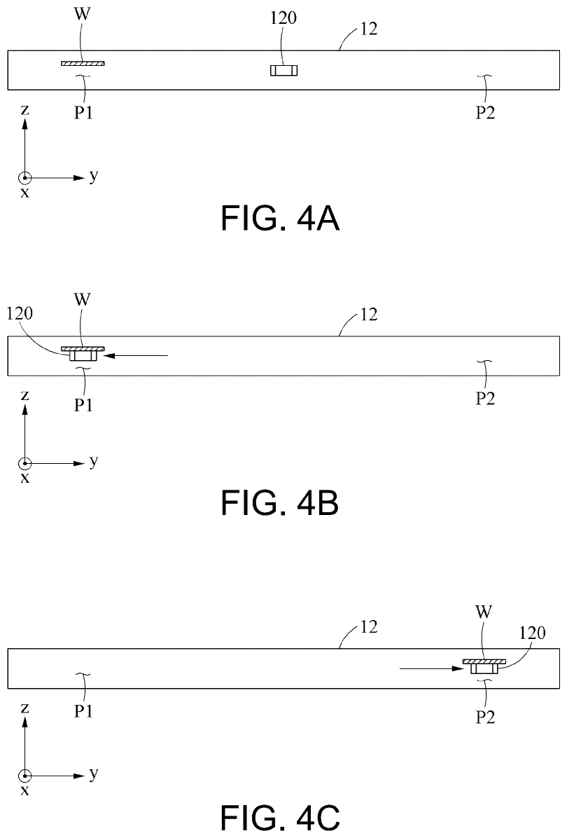

FIGS. 4A to 4C are schematic front views to illustrate a treatment process of a substrate W.

Referring to FIGS. 4A to 4C, the horizontal return robot 12 may transfer a plurality of substrates W between a plurality of the chamber portions 10 in a horizontal direction. For example, the horizontal return robot 12 may iteratively reciprocate between the first and second points P1 and P2. The horizontal return robot 12 may include the sixth gripping portion 120. The sixth gripping portion 120 may grip the substrate W placed on the first point P1 and may move to the second point P2.

In FIG. 4A, the substrate W may be loaded to the first point P1. The first point P1 may function as a stage before the sixth gripping portion 120 transfers the substrate W.

Referring to FIG. 4B, when the substrate W is loaded to the first point P1, the horizontal return robot 12 may move to the first point P1 to grip the substrate W. However, the examples are not limited thereto. For example, even before the substrate W is loaded to the first point P1, the horizontal return robot 12 may move to the first point P1 in advance and wait at the first point P1.

Referring to FIG. 4C, when the horizontal return robot 12 grips the substrate W at the first point P1, the horizontal return robot 12 may move to the second point P2. That is, the horizontal return robot 12 may transfer the substrate W from the first point P1 to the second point P2. The second point P2 may function as a stage before the second vertical return robot (for example, the second vertical return robot 111 of FIG. 1) grips the substrate W.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. For example, suitable results may be achieved if the described techniques are performed in a different order and/or if components in a described system, architecture, device, or circuit are combined in a different manner and/or replaced or supplemented by other components or their equivalents.

Accordingly, other implementations are within the scope of the following claims.

What is claimed is:

1. A substrate treatment line comprising:
a plurality of chamber portions each comprising a plurality of treatment chambers stacked in a vertical direction, the plurality of chamber portions each disposed at an interval in a horizontal direction;
a first vertical return robot, comprising a plurality of gripping portions, a number of the plurality of gripping portions equal to a number of the plurality of treatment chambers in a first chamber portion of the plurality of chamber portions, the first vertical return robot configured to move in a vertical direction to transfer a plurality of substrates in a vertical direction each from one treatment chamber of the plurality of treatment chambers vertically stacked upon each other in the first chamber portion to another treatment chamber of the plurality of treatment chambers in the first chamber portion while the first vertical return robot and the plurality of gripping portions remain extending along a vertical plane, the first vertical return robot further configured to move in a vertical direction to simultaneously transfer substrates to each of a first point arranged above the first chamber portion and at least one of the plurality of treatment chambers in the first chamber portion while the first vertical return robot and the plurality of gripping portions remain extending along the vertical plane;
a second vertical return robot, comprising a plurality of gripping portions, a number of the plurality of gripping portions equal to a number of the plurality of treatment chambers in a second chamber portion of the plurality of chamber portions, the second vertical return robot configured to move in a vertical direction to transfer a plurality of substrates in a vertical direction each from one treatment chamber of the plurality of treatment chambers vertically stacked upon each other in the second chamber portion to another treatment chamber of the plurality of treatment chambers in the second chamber portion while the second vertical return robot and the plurality of gripping portions remain extending along the vertical plane, the second vertical return robot further configured to move in a vertical direction to simultaneously unload substrates from each of a second point arranged above the second chamber portion and at least one of the plurality of treatment chambers in the second chamber portion while the second vertical return robot and the plurality of gripping portions remain extending along the vertical plane; and
a horizontal return robot to transfer the substrates between the plurality of chamber portions in a horizontal direction, the horizontal return robot comprising a gripping portion to grip a substrate placed on the first point above the first chamber portion and transfer the substrate to the second point above the second chamber portion while the gripping portion remains perpendicular to the vertical plane;
wherein the first vertical return robot and the second vertical return robot are positioned on the vertical plane, the vertical plane extending from the first chamber portion to the second chamber portion, wherein the first vertical return robot and the second vertical return robot are configured to move vertically along the vertical plane, wherein the gripping portions of the first vertical return robot extend horizontally along the vertical plane in a direction opposite from a horizontal direction along the vertical plane in which the gripping portions of the second vertical return robot extend, wherein the first point and the second point are positioned on the vertical plane,
wherein the horizontal return robot is provided separately from the first vertical return robot and the second vertical return robot.

2. The substrate treatment line of claim 1, wherein the first vertical return robot to load, unload, or vertically transfer the substrates from or to the first chamber portion and the second vertical return robot to load, unload, or vertically transfer the substrates from or to the second chamber portion.

3. The substrate treatment line of claim 2, wherein the treatment chambers of the first chamber portion comprise a first treatment chamber, a second treatment chamber, and a third treatment chamber, and the treatment chambers of the second chamber portion comprise a fourth treatment chamber and a fifth treatment chamber.

4. The substrate treatment line of claim 3, wherein the first treatment chamber, the second treatment chamber, and the third treatment chamber are sequentially stacked on each other from bottom to top, and the fourth treatment chamber and the fifth treatment chamber are sequentially stacked on each other from top to bottom.

5. The substrate treatment line of claim 4, wherein the first to third treatment chambers are each provided as a contact cleaning chamber, and the fourth and fifth treatment chambers are each provided as a non-contact cleaning chamber or a drying chamber.

6. The substrate treatment line of claim 4, wherein the first vertical return robot comprises a first gripping portion, a second gripping portion and a third gripping portion to grip a substrate.

7. The substrate treatment line of claim 6, wherein the first vertical return robot may transition between a first state having a first height and a second state having a second height that is higher than the first height.

8. The substrate treatment line of claim 7, wherein, in the first state, the first to third gripping portions are placed at heights corresponding to the first to third treatment chambers.

9. The substrate treatment line of claim 8, wherein, in the first state, the first vertical return robot grips and unloads substrates treated in the first to the third treatment chambers.

10. The substrate treatment line of claim 9, wherein the first vertical return robot transitions to the second state in which the first and the second gripping portions load substrates to the second and third treatment chambers and the third gripping portion loads a substrate to the first point, and transitions to the first state.

11. The substrate treatment line of claim 4, wherein the second vertical return robot comprises a fourth gripping portion and a fifth gripping portion to grip a substrate.

12. The substrate treatment line of claim 11, wherein the second vertical return robot transitions between a third state having a third height and a fourth state having a fourth height that is lower than the third height.

13. The substrate treatment line of claim 12, wherein in the fourth state, the fourth and fifth gripping portions are placed at heights corresponding to the fourth to fifth treatment chambers.

14. The substrate treatment line of claim 13, wherein, in the third state, the second vertical return robot grips and unloads a substrate placed on the second point and a substrate treated in the fourth treatment chamber.

15. The substrate treatment line of claim 14, wherein the second vertical return robot transitions to the fourth state in which the fourth and the fifth gripping portions load substrates to the fourth and fifth treatment chambers and transitions to the third state.

16. The substrate treatment line of claim 4, wherein the horizontal return robot comprises a sixth gripping portion to grip a substrate placed on the first point arranged above the first chamber portion and transfer the substrate to the second point, the second point arranged above the second chamber portion.
